(19) United States
(12) Patent Application Publication
(10) Pub. No.: US 2026/0236232 A1
(43) Pub. Date: Aug. 13, 2026

(54) OPERATION PROGRAM GENERATION APPARATUS AND OPERATION PROGRAM GENERATION METHOD

(71) Applicant: KAWASAKI JUKOGYO KABUSHIKI KAISHA, Kobe-shi, Hyogo (JP)

(72) Inventors: Keisuke SUGANO, Kobe-shi (JP); Toshihiko MIYAZAKI, Kobe-shi (JP); Kazutsugu SUITA, Kobe-shi (JP)

(73) Assignee: KAWASAKI JUKOGYO KABUSHIKI KAISHA, Kobe-shi, Hyogo (JP)

(21) Appl. No.: 19/470,930

(22) PCT Filed: Mar. 22, 2024
(86) PCT No.: PCT/JP2024/011315

§ 371 Date: Sep. 30, 2025

(30) Foreign Application Priority Data
Apr. 3, 2023 (JP) 2023-060044

(51) Int. Cl. G06F 8/30; G06F 30/20

(52) U.S. Cl. CPC G06F 8/30; G06F 30/20

(57) ABSTRACT

A motion program generation apparatus (100) according to this disclosure includes generates a provisional motion program based on the input information on the motion, simulates power consumption of the robot system when the constituent components are virtually moved according to the provisional operation program, receives an input of instruction to modify the information on the operation of the robot system based on a result of the simulation, and generates an actual operation program.

### TECHNICAL FIELD

The present disclosure relates to an operation program generation apparatus and an operation program generation method.

### BACKGROUND ART

Robot operation program generation apparatuses are disclosed in the art. For example, Japanese Patent Publication No. JP 5890477 discloses a program modification apparatus for modifying an operation program of a single robot. The program modification apparatus in Japanese Patent Publication No. JP 5890477 includes a simulation unit which performs a simulation on the basis of the operation program, and a program modifier which modifies the operation program so that a result of the simulation satisfies an evaluation basis decided in advance while the simulation unit repeatedly performs the simulation. Specifically, a command speed and a command acceleration at a teaching point of the robot are modified in the operation program to satisfy the evaluation basis. In the program modification apparatus in Japanese Patent Publication No. JP 5890477, for example, power consumption is set as the evaluation basis.

### PRIOR ART

### Patent Document

Patent Document 1: Japanese Patent Publication No. JP 5890477

### SUMMARY OF THE INVENTION

On one hand, in the program modification apparatus in Japanese Patent Publication No. JP 5890477, the operation program for the single robot is modified so that the power consumption satisfy the desired power consumption. On the other hand, in the manufacturing industries, service fields and the like, systems in which robots operate in cooperation with each other, or robot systems in which robots and machining shafts operate in cooperation with each other have been introduced. For this reason, it is desirable to appropriately and precisely generate operation programs for robot systems from the viewpoint of power consumption.

The present disclosure is intended to solve the above problem, and one object of the present disclosure is to provide an operation program generation apparatus and an operation program generation method capable of appropriately and precisely generating an operation program for a robot system from the viewpoint of power consumption.

An operation program generation apparatus according to a first aspect of the present disclosure includes an input receiver that receives an input of information on operation of a robot system including constituent components including robots; an operation program generator that generates a provisional operation program based on the input information on the operation; a power consumption calculator that simulates power consumption of the robot system when the constituent components are virtually operated according to the generated provisional operation program, wherein the input receiver receives an input of instruction to modify the information on the operation of the robot system based on a result of the simulated power consumption, and the operation program generator generates an actual operation program based on the modified information on the operation of the robot system.

In the operation program generation apparatus according to the first aspect of the present disclosure, as discussed above, a power consumption calculator that simulates power consumption of the robot system when the constituent components are virtually operated according to the generated provisional operation program is provided. Accordingly, the overall power consumption of the robot system can be simulated based on the provisional operation program for the robot system. In addition, the input receiver receives an input of instruction to modify the information on the operation of the robot system based on a result of the simulated power consumption, and the operation program generator generates an actual operation program based on the modified information on the operation of the robot system. Accordingly, an appropriate and precise actual operation program modified based on the result of the power consumption simulation can be generated. Therefore, it is possible to appropriately and precisely generate an operation program for a robot system from the viewpoint of power consumption.

An operation program generation method according to a second aspect of the present disclosure includes receiving an input of information on operation of a robot system including constituent components including robots; generating a provisional operation program based on the input information on the operation; simulating power consumption of the robot system when the constituent components are virtually operated according to the generated provisional operation program; receiving an instruction to modify the information on the operation of the robot system based on a result of the simulated power consumption; and generating an actual operation program based on the modified information on the operation of the robot system.

In the operation program generation method according to the second aspect of the present disclosure, as discussed above, simulating power consumption of the robot system when the constituent components are virtually operated according to the generated provisional operation program is provided. Accordingly, the overall power consumption of the robot system can be simulated based on the provisional operation program for the robot system. In addition, in the operation program generation method, receiving an instruction to modify the information on the operation of the robot system based on a result of the simulated power consumption, and generating an actual operation program based on the modified information on the operation of the robot system are provided. Accordingly, an appropriate and precise actual operation program modified based on the result of the power consumption simulation can be generated. Therefore, it is possible to provide an operation program generation method capable of appropriately and precisely generating an operation program for a robot system from the viewpoint of power consumption.

According to an operation program generation apparatus and an operation program generation method of the present disclosure, it is possible to appropriately and precisely generate an operation program for a robot system from the viewpoint of power consumption.

### BRIEF DESCRIPTION OF THE DRAWINGS

FIG. 1 is a block diagram schematically showing an operation program generation apparatus and a robot system according to one embodiment.

FIG. 2 is a view showing a robot and a machining shaft according to the one embodiment.

FIG. 3 is a block diagram showing an operation program generation apparatus according to the one embodiment.

FIG. 4 is a flowchart illustrating operation of the operation program generation apparatus according to the one embodiment.

FIG. 5 is a diagram illustrating an operation trajectory.

### MODES FOR CARRYING OUT THE INVENTION

The following description will describe one embodiment embodying the present disclosure with reference to the drawings.

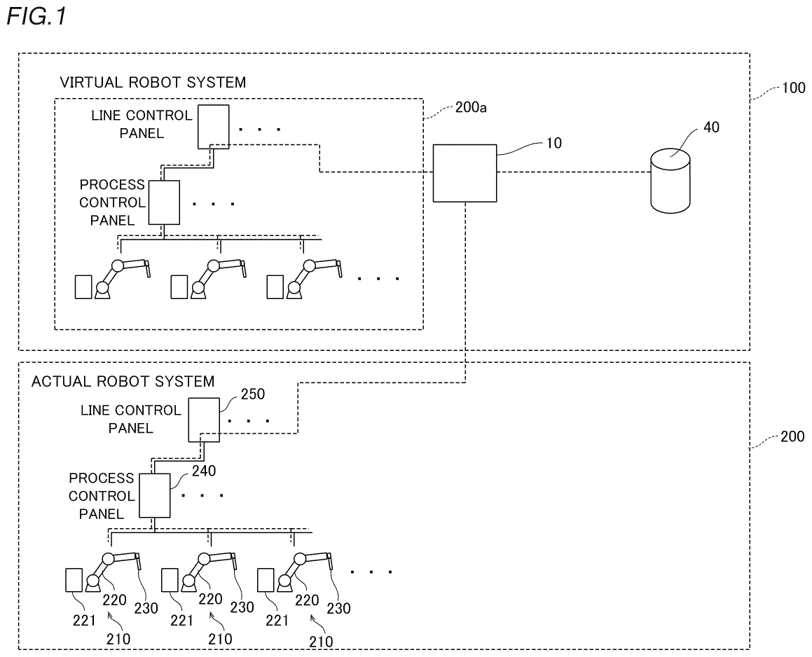

As shown in FIG. 1, an operation program generation apparatus 100 is an apparatus that generates operation programs for a robot system 200.

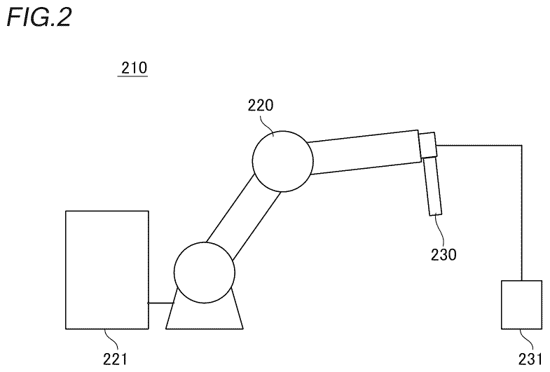

As shown in FIG. 1, the actual robot system 200 includes constituent components 210 including robots 220. In this embodiment, as shown in FIG. 2, the constituent components 210 include machining shafts 230 in addition to the robots 220. Each machining shaft 230 is, for example, a welding torch attached to a distal end of a corresponding one of the robot 220. Here, a plurality of robots are provided as the robots 220. The number of machining shafts 230 corresponds to the number of robots 220. In addition, the robot system 200 includes power supplies 231 supplying power to the machining shafts 230. Here, the robots 220 are not limited to industrial robots to which welding torches or the like are attached, but may be service robots, such as nursing care robots. Also, each robot 220 includes joints. Each joint includes an electric motor that drives the joint and an encoder that detects the rotation angle of the electric motor.

As shown in FIG. 1, the robot system 200 includes robot controllers 221, process control panels 240, and line control panels 250. Each robot controller 221 is provided for a corresponding one of the robots 220. Each robot controller 221 includes a servo amplifier that supplies power to the electric motors, which are arranged at the joints of the robot 220. Each process control panel 240 controls the robots 220. Each line control panel 250 controls the process control panels 240.

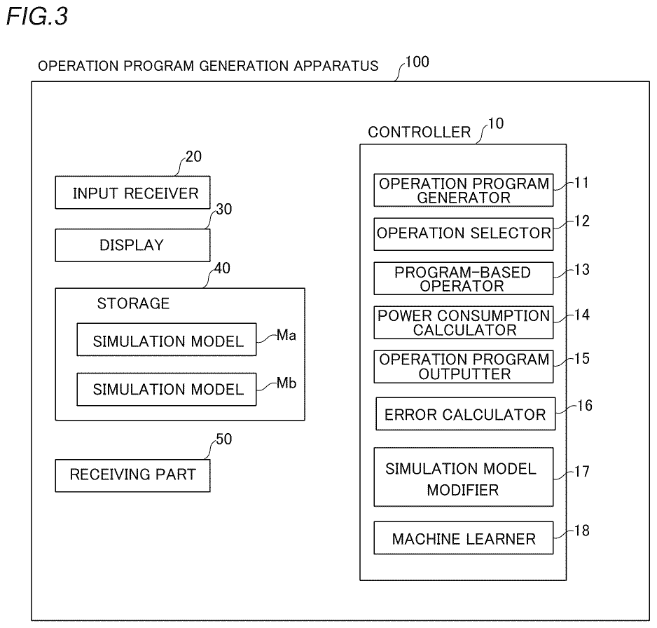

As shown in FIG. 3, the operation program generation apparatus 100 includes a controller 10, an input receiver 20, a display 30, a storage 40, and a receiving part 50. The controller 10 includes an operation program generator 11, an operation selector 12, a program-based operator 13, a power consumption calculator 14, an operation program outputter 15, an error calculator 16, a simulation model modifier 17, and a machine learner 18. The operation program generation apparatus 100 is, for example, a personal computer. The input receiver 20 is, for example, a keyboard, a mouse, or the like. The controller 10 includes a CPU (Central Processing Unit), a ROM (Read Only Memory), a RAM (Random Access Memory) and the like.

The display 30 is, for example, a liquid crystal display. The storage 40 may be a hard disk arranged inside the operation program generation apparatus 100, or a server connected to the operation program generation apparatus 100 via a network. The storage 40 stores a simulation model Ma that simulates power consumption of the robots 220 when the robots 220 are operated, and a simulation model Mb that simulates power consumption of the machining shafts 230 when the machining shafts 230 are operated. The receiving part 50 receives current values and the like measured in the robot system 200. The receiving part 50 is an interface, such as a connector, for example.

As shown in FIG. 1, the operation program generation apparatus 100 virtually generates a robot system 200a, which has the same configuration as the actual robot system 200. The operation program generation apparatus 100 virtually operates the robot system 200a based on the generated operation program. The following description describes operation of the controller 10 of the operation program generation apparatus 100.

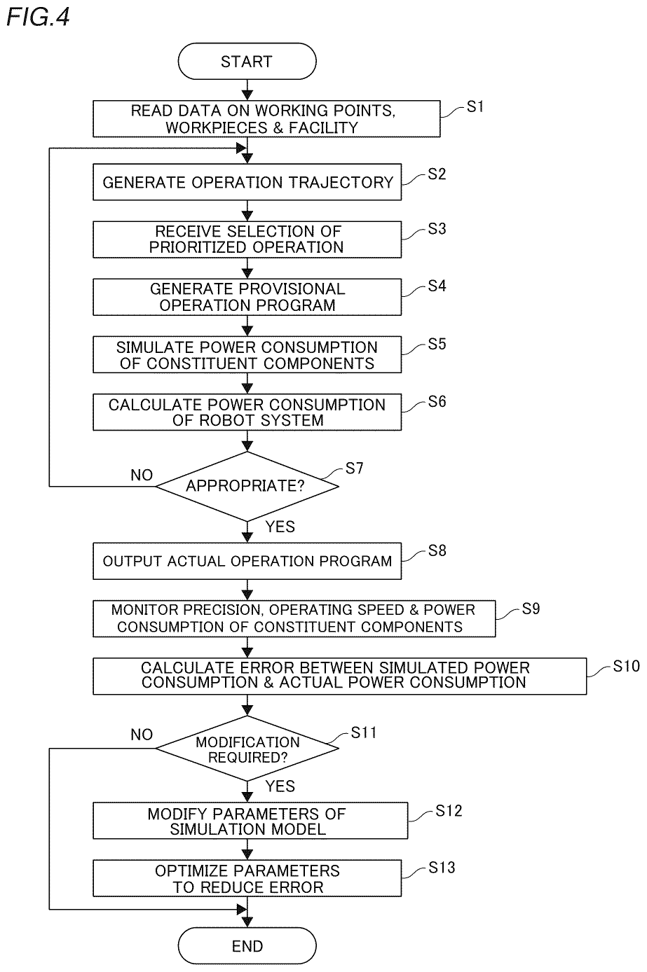

As shown in FIG. 4, in step S1, the input receiver 20 receives inputs of working points of the constituent components 210. The working points of the constituent component 210 are, for example, teaching points, which are data on positions and postures of the robots 220. The data on positions and postures of the robots 220 includes rotation angles of joints of the robots 220. Also, the working points of the constituent components 210 are, for example, positions at which the machining shafts 230 perform machining. Also, the input receiver 20 receives inputs of information on workpieces to be processed by the constituent components 210. The information on the workpieces includes, for example, types and shapes of the workpieces. Also, the input receiver 20 receives data on a facility where the robot system 200 is arranged. The data on the facility includes locations where the constituent components 210 are arranged and operating ranges of the constituent components 210. Specifically, the data on the facility includes the system configuration of the facility, operating conditions of the facility, and operational setting information on the facility. The system configuration of the facility includes information on the robots 220, the machining shafts 230, and other peripheral devices. Also, the operating conditions of the facility include operating schedules, cycle times and the like. Also, the operational setting information on the facility includes, for example, operating modes, setting information on environmental changes, and the like. Here, the operating modes are an operation that prioritizes power consumption, an operation that prioritizes precision of the constituent components 210, and an operation that prioritizes operating speed of the constituent components 210 as described later. Also, inputs of the working points, the information on workpiece, and the data on the facility are performed by an operator.

In step S2, the input receiver 20 receives inputs of information on operation of the robot system 200 including constituent components 210 including the robot 220. The inputs of the information on operation of the robot system 200 are performed by the operator. Specifically, in this embodiment, the input receiver 20 receives inputs of information on interlock of at least one of the constituent components 210 as the information on the operation of the robot system 200. In other words, the input receiver 20 receives the inputs of the information on interlock that allow one robot 220 among the robots 220 to operate while preventing the operation of the other robots 220. For example, the input receiver 20 receives inputs indicating which robot 220 is to be interlocked and the timing of the interlock in a series of operations of the robot system 200.

In this embodiment, the input receiver 20 receives inputs of information on the constituent components 210 in operating and information on the constituent components in standby as the information on the operation of the robot system 200. For example, the input receiver 20 receives inputs of periods of time during which the robots 220 are in their operating states, and periods of time during which the robots 220 are in their standby states in a Series of operations of the robot system 200.

In this embodiment, the input receiver 20 receives inputs of information on power disconnection of the constituent components 210 as the information on the operation of the robot system 200. For example, the input receiver 20 receives inputs of the timing of power disconnection of the power supplies 231 from the machining shafts 230 in a series of operations of the robot system 200. Also, the input receiver 20 receives inputs of information on the timing of reconnection of the power supplies 231 to the machining shafts 230 in a series of operations of the robot system 200.

Subsequently, the operation program generator 11 generates a provisional operation program based on the input information on the operation. Specifically, the operation program generator 11 generates, as the provisional operation program, an operation trajectory of the constituent components 210 when the constituent components 210 are virtually operated.

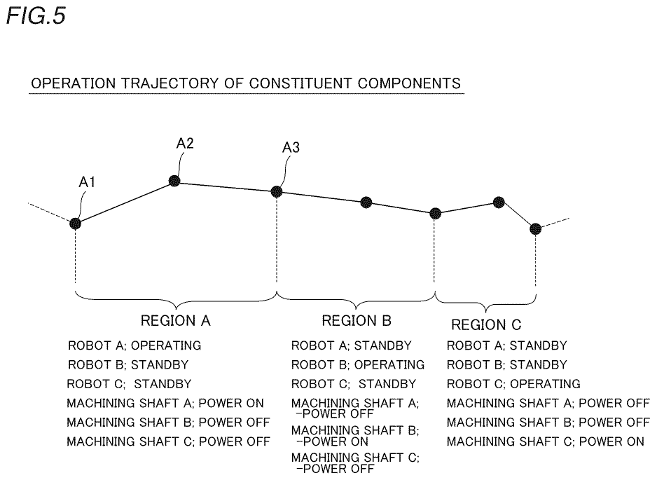

An operation trajectory is described in a case where the robot system 200 includes robots A, B and C, and machining shafts A, B, and C as one example with reference to FIG. 5. As a series of operation trajectories of the robot system 200, in a region A, the robot A is operated to pass through teaching points A1, A2 and A3, and the machining shaft A attached to the robot A performs welding processing at the teaching points A1, A2 and A3. The same applies for regions B and C. In addition, in the region A, the robot B and the robot C are interlocked. In addition, in the region A, the robot A is in its operating state, while the robot B and the robot C are in their standby states. In addition, in the region A, the power supply 231 for the machining shaft A that is attached to the robot A is connected, while the power supply 231 for the machining shaft B attached to the robot B and the power supply 231 for the machining shaft C attached to the robot C are disconnected. Such a series of operations of the robot system 200 is defined in the provisional operation program. Here, when the machining shafts 230 perform spot welding, their machining pressures in the spot welding are controlled by controlling servo motors that are arranged at the joints of their corresponding robots 220. Here, welding currents in the spot welding are controlled by the robot controllers 221. For example, when the machining shaft A in the region A performs spot welding, control of its processing pressure and control of its welding current in the spot welding are defined in the provisional operation program for the operation in the region A.

In step S3, in this embodiment, the operation selector 12 receives a selection of which operation to execute among the operation that prioritizes power consumption, the operation that prioritizes precision of the constituent components 210, and the operation that prioritizes operating speed of the constituent components 210 for each region of the generated operation trajectory. For example, the operator selects one of the operations by operating the keyboard, mouse, or the like. For example, in the region A, the operation that prioritizes power consumption is selected. In the region B, the operation that prioritizes precision of the constituent components 210 is selected. In the region C, the operation that prioritizes operating speed of the constituent components 210 is selected. In a case of an operation trajectory where a workpiece is conveyed, there are teaching points that require high precision for the workpiece to pass through exactly, and teaching points that allow for some tolerance in precision. At the teaching points that allow for some tolerance in precision, priority is given to reduce power consumption. For this reason, at the teaching points that allow for some tolerance in precision, the operation that prioritizes power consumption is selected. Also, at the teaching points that require high precision, the operation that prioritizes precision of the constituent components 210 is selected. In this case, the power consumption of the robot 220 is higher than the operation that prioritizes precision. In the operation that prioritizes operating speed of the constituent components 210, the power consumption of the robot 220 is increased by operating the robot 220 at a higher speed. For example, when the robot 220 takes a certain action, an operation of the robot 220 that minimizes the operation time of the robot 220 is selected. Also, when high precision is required and the robot must operate through these teaching points at a higher speed in the operation trajectory, such as in cases where both the operation that prioritizes precision of the constituent components 210 and the operation that prioritizes operating speed of the constituent components 210 are selected, control is executed to maximize the performance of the robot 220. As a result, although the power consumption of the robot 220 is increased, the power consumption of the robot 220 can be reduced by creating the operation trajectory to minimize such a region in which the robot must operate at a higher speed. Here, the operating speed of the robot 220 is changed by adjusting its command speed and command acceleration at the teaching point.

In cases where the robots are relatively frequently in interlocked states so that the cycle time of a series of processes performed by the robot system 200 is not reduced by abruptly accelerating and decelerating operation of the robots 22, the operation program can be modified to smoothly accelerate and decelerate the operation of the robots 22 by selecting the operation that prioritizes power consumption of the constituent components 210. Accordingly, it is possible to reduce power consumption of the robot system 200. Also, in cases where the robots 22 are relatively widely operated, a balance between the prioritization of precision and operating speed and the prioritization of power consumption can be achieved by reducing regions in which the operation that prioritizes precision of the constituent components 210 and the operation that prioritizes operating speed of the constituent components 210 are selected, and by increasing regions in which the operation that prioritizes power consumption of the constituent components 210 is selected. Also, in cases where the robots 22 are relatively widely operated, it is effective from the viewpoint of reducing power consumption to generate an operation trajectory that minimizes the operation trajectory along which the robots 22 operate. Also, in cases where arms of the robots 22 can operate in a direction of their own weight are applied, it is effective from the viewpoint of reducing power consumption to generate an operation trajectory that allows generation of regenerative energy.

In step S4, the program-based operator 13 virtually operates the constituent components 210 according to the generated provisional operation program.

In this embodiment, in step S5 and step S6, the power consumption calculator 14 simulates power consumption of the robot system 200 when the constituent components 210 are virtually operated according to the generated provisional operation program. Specifically, in step S5, the power consumption calculator 14 simulates the power consumption of individual robots 220 in the robot system 200 using the simulation model Ma. In addition, the power consumption calculator 14 simulates the power consumption of the individual machining shafts 230 in the robot system 200 using the simulation model Mb. For example, the power consumption calculator 14 simulates the power consumption of the robot 220 based on values of current that flows through the electric motors, values of current that flows through the servo amplifiers, and values of current that flows through the robot controllers 221 when the robots 220 are driven. In addition, the power consumption calculator 14 simulates the power consumption of the power supplies 231, which supply power to the machining shafts 230 such as welding torches controlled by the robot controllers 221. The simulation models Ma and Mb include parameters for simulating the power consumption. The parameters included in the simulation models Ma and Mb are, for example, gains used in the calculation of power consumption corresponding to command speeds given to the electric motors, gains used in the calculation of power consumption corresponding to command accelerations given to the electric motors, and the like. In addition, the calculated power consumption of each of the constituent components 210 is indicated on the display 30.

In this embodiment, the power consumption calculator 14 simulates the power consumption of the robot system 200 when the constituent components 210 are operated according to the operation trajectory that is prioritized by the selection for each region. In the example shown in FIG. 5, in the region A, the power consumption is simulated provided that the robots 220 perform the operation that prioritizes power consumption. In addition, appropriate operations for the regions A, B and C are selected based on results of the simulation to minimize the total power consumption in a case of passage through the regions A, B and C.

In this embodiment, the power consumption calculator 14 simulates the power consumption of the robot system 200 including the constituent components 210 that are interlocked. In the example shown in FIG. 5, in the region A, the power consumption is simulated provided that the robots B and C are interlocked. Here, although the power consumption of the robot 220 that operates in each region is estimated by simulation in the example shown in FIG. 5, the power consumption of the robots 220 that are interlocked and standing by can be estimated by simulation, and energy required to maintain postures of these robots 220 by applying mechanical brakes to the robots 220 can be minimized.

In this embodiment, the power consumption calculator 14 simulates the power consumption of the robot system 200 including the constituent components 210 in their operating states and the constituent components 210 in their standby states. In the example shown in FIG. 5, in the region A, power consumption of the robot A in its operating states is simulated, and power consumption of the robots B and C in their standby state is simulated.

In this embodiment, the power consumption calculator 14 simulates the power consumption of the robot system 200 including the constituent components 210 whose power is disconnected. In the example shown in FIG. 5, in the region A, power consumption of the machining shaft A with its power supply A connected, and power consumption of the machining shaft B and the machining shaft C with their the power supplies disconnected is simulated.

In this embodiment, the power consumption calculator 14 simulates, in a time series, the power consumption of the constituent components 210 including the difference in regenerative energy of the constituent components 210.

The power consumption and the regenerative energy of the constituent components 210 change constantly. The power consumption calculator 14 calculates the power consumption including the difference in regenerative energy, which changes constantly. The power consumption calculator 14 simulates a time variation in acceleration of the electric motors arranged at the joints, a time variation in speed of the electric motors arranged at the joints, the maximum value of acceleration, the maximum value of the speed, an average value of acceleration, an average value of the speed, and the cumulative value of power consumption in a time series.

In step S6, the power consumption calculator 14 calculates the power consumption of the robot system 200 by summing power consumption values of the constituent components 210 included in the robot system 200. In addition, the calculated power consumption of the robot system 200 is indicated on the display 30.

In step S7, the operator determines whether the calculated power consumption values of the constituent components 210 and the calculated power consumption of the robot system 200 are appropriate. In a case where the operator determines that they are not appropriate, the operator inputs information indicating that they are not appropriate using the input receiver 20. In this case, the procedure returns to step S2. In other words, in this embodiment, the input receiver 20 receives inputs of instruction to modify information on the operation of the robot system 200 based on results of the simulated power consumption. Specifically, the display 30 indicates the simulation results of the power consumption of the robot system 200 simulated by the power consumption calculator 14. The operator inputs information on operation of the robot system 200 again based on the simulation results indicated on the display 30. For example, the operator modifies information on interlock, information on the constituent components in operating and in standby, information on disconnection of power supplies, the prioritized operation in each operation region to reduce the power consumption of the robot system 200. The operation program generator 11 modifies the provisional operation program based on the modified information on the operation of the robot system 200. The power consumption calculator 14 simulates the power consumption of the robot system 200 according to the modified provisional operation program.

In a case where the operator determines that they are appropriate in step S7, the operator inputs information indicating that they are appropriate using the input receiver 20. The operation program generator 11 generates an actual operation program based on the modified information on the operation of the robot system 200.

In this embodiment, the storage 40 stores the actual operation program generated by the operation program generator 11. In other words, when the operator can accept the simulation results of the power consumption of the robot system 200 after modifying the provisional operation program, the modified provisional operation program is stored in the storage 40 as the actual operation program. Subsequently, the procedure goes to step S8.

In this embodiment, in step S8, the operation program outputter 15 outputs the generated actual operation program to the robot system 200. For example, the operation program outputter 15 outputs the actual operation program to the robot system 200 based on the operator's operation using the input receiver 20. The operation program outputter 15 outputs the actual operation program to the line control panels 250 in the robot system 200. Accordingly, the robot system 200 operates according to the actual operation program.

In step S9, the controller 10 monitors the power consumption of the constituent components 210, the precision of the constituent components 210, and the operating speed of the constituent components 210. For example, electric current meters are respectively provided for the constituent components 210, and the receiving part 50 receives measurement currents detected by the respective current meters. The controller 10 calculates actual power consumption based on the current values received by the receiving part 50. Also, the constituent components 210 may retain data on a power amount consumed by the constituent components 210 themselves. Based on the power consumption retained by the constituent components 210, the actual power consumption of the constituent components 210 may be acquired when they are actually operated. Encoders that detect rotation angles of the electric motors are provided for the constituent components 210. The receiving part 50 receives the rotation angles of the electric motors detected by the encoders. The controller 10 calculates precision of the constituent components 210 and operating speed of the constituent components 210 based on the rotation angles of the electric motors received by the receiving part 50.

In this embodiment, in step S10, the error calculator 16 calculates an error between the actual power consumption of the constituent components 210 when the constituent components are actually operated according to the actual operation program output from the operation program outputter 15 and the power consumption calculated by the simulation.

In step S11, the operator determines whether the error calculated by the error calculator 16 is appropriate. The error is indicated, for example, on the display 30. In a case where the operator determines that it is not appropriate, the operator inputs information indicating that it is not appropriate using the input receiver 20. In this case, the procedure goes to step S12. In a case where the operator determines that it is appropriate, the operator inputs information indicating that it is appropriate using the input receiver 20. In this case, the operation of the operation program generation apparatus 100 is terminated.

In step S12, in this embodiment, the simulation model modifier 17 modifies the parameters included in the simulation models Ma and Mb simulating the power consumption of the robot system 200 based on the error calculated by the error calculator 16. The simulation model modifier 17 modifies the gains for the calculation of power consumption corresponding to command speeds given to the electric motors, the gains for the calculation of power consumption corresponding to command accelerations given to the electric motors, and the like included in the simulation models Ma and Mb. For example, the simulation model modifier 17 uses feedback control to modify the parameters included in the simulation models Ma and Mb.

In this embodiment, in step S13, the machine learner 18 optimizes the parameters included in the simulation models Ma and Mb using machine learning to reduce the error calculated by the error calculator 16. For example, the parameters and the error are learned by the machine learner 18 while the parameters included in the simulation models Ma and Mb are modified multiple times. Subsequently, the machine learner 18 optimizes the parameters based on machine learning to minimize the error calculated by the error calculator 16. For example, the machine learner 18 determines parameters to reduce the error calculated by the error calculator 16 below a predetermined threshold. After that, the operation of the operation program generation apparatus 100 is terminated.

Here, after the parameters in the simulation models Ma and Mb are modified, the procedure may return to step S5 so that the power consumption of the robot system 200 can be simulated again.

### Advantages of the Embodiment

The operation program generation apparatus 100 includes the power consumption calculator 14 that simulates power consumption of the robot system 200 when the constituent components 210 are virtually operated according to a generated provisional operation program. Accordingly, the overall power consumption of the robot system 200 can be simulated based on the provisional operation program for the robot system 200. In addition, the input receiver 20 receives inputs of instruction to modify information on operation of the robot system 200 based on results of the simulated power consumption, and the operation program generator 11 generates an actual operation program based on the modified information on the operation of the robot system 200. Accordingly, an appropriate and precise actual operation program modified based on the result of the power consumption simulation can be generated. Therefore, it is possible to appropriately and precisely generate an operation program for the robot system 200 from the viewpoint of power consumption.

The operation program generator 11 generates, as the provisional operation program, an operation trajectory of the constituent components 210 when the constituent components 210 are virtually operated. The operation program generation apparatus 100 includes the operation selector 12 that receives a selection of which operation to execute among an operation that prioritizes power consumption, an operation that prioritizes precision of the constituent components 210, and an operation that prioritizes operating speed of the constituent components 210 for each region of the generated operation trajectory. Accordingly, different prioritized operations can be assigned to respective regions of the operation trajectory. As a result, the operation program can be generated more appropriately for the entire operation trajectory as compared with a case where the operation program is generated solely from the viewpoint of power consumption.

The power consumption calculator 14 simulates the power consumption of the robot system 200 when the constituent components 210 are operated according to the operation trajectory that is prioritized by the selection for each region. Accordingly, it is possible to simulate power consumption of the robot system 200 that assigns different prioritized operations to respective regions of the operation trajectory.

The input receiver 20 receives inputs of information on interlock of at least one of the constituent components 210 as information on the operation of the robot system 200, and the power consumption calculator 14 simulates the power consumption of the robot system 200 including the constituent components 210 that are interlocked. Here, when the constituent components 210 operate in unison, it is assumed that the interlock causes frequent repetition of operation starts and stops of the constituent components 210. To address this, the operation program can be modified by receiving inputs of information on interlock through the input receiver 20 in order to minimize stopping states of the constituent components 210 caused by the interlock and to minimize stopping duration of the constituent components 210 and the number of accelerations and decelerations of the constituent components 210. Consequently, the processing performance of the robot system 200 can be optimized while minimizing the overall power consumption of the robot system 200.

The input receiver 20 receives inputs of information on the constituent components 210 in operating and information on the constituent components in standby as the information on the operation of the robot system 200, and the power consumption calculator 14 calculator simulates the power consumption of the robot system 200 including the constituent components 210 in their operating states and the constituent components 210 in their standby states. Here, during operation of the robot system 200, the constituent components 210 will be in operating or in standby. The power consumption of the constituent components 210 in operating and the power consumption of the constituent components in standby are different from each other. For this reason, the operation program of the robot system 200 can be generated more appropriately from the viewpoint of power consumption by receiving inputs of information on the constituent components 210 in operating and information on the constituent components in standby through the input receiver 20.

The input receiver 20 receives inputs of information on power disconnection of the constituent components 210 as the information on the operation of the robot system 200, and the power consumption calculator 14 simulates the power consumption of the robot system 200 including the constituent components 210 whose power is disconnected. Here, during operation of the robot system 200, power supplies may be disconnected from the constituent components 210 in some occasions. For this reason, the operation program of the robot system 200 can be generated more appropriately from the viewpoint of power consumption by receiving inputs of information on power disconnection of the constituent components 210 through the input receiver 20.

The power consumption calculator 14 simulates the power consumption of the robot system 200 including the difference in regenerative energy of the constituent components 210. For example, electric motors are arranged at joints of the robots 220 as the constituent components 210. During rotational deceleration of the joints, regenerative energy is generated by the electric motors.

This regenerative energy may be used as power to drive the electric motors in some cases. To address this, the power consumption of the robot 220 that uses regenerative energy can be precisely calculated by simulating the power consumption of the robot system 200 including the difference in regenerative energy of the constituent components 210 through the power consumption calculator 14.

The power consumption calculator 14 simulates, in a time series, the power consumption of the constituent components 210 including the difference in regenerative energy of the constituent components 210. Accordingly, the power consumption of the constituent components, which changes constantly, can be grasped by the simulation, and as a result the operation program of the robot system 200 can be generated more appropriately from the viewpoint of power consumption.

The operation program generation apparatus 100 includes the storage 40 that stores the actual operation program generated by the operation program generator 11.

Accordingly, the actual robot system 200 can be operated according to the operation program stored in the storage 40.

The operation program generation apparatus 100 includes the operation program outputter 15 that outputs the generated actual operation program to the robot system 200; and the error calculator 16 that calculates an error between the actual power consumption of the constituent components when the constituent components 210 are actually operated according to the actual operation program output from the operation program outputter 15 and the power consumption calculated by the simulation. Accordingly, operators can determine precision of the simulation based on the error.

The operation program generation apparatus 100 includes the simulation model modifier 17 that modifies the parameters included in the simulation models Ma and Mb simulating the power consumption of the robot system 200 based on the error calculated by the error calculator 16. Accordingly, the simulation models Ma and Mb can be modified more precisely.

The operation program generation apparatus 100 includes the machine learner 18 that optimizes the parameters included in the simulation models Ma and Mb using machine learning to reduce the error calculated by the error calculator 16. Accordingly, parameters can be appropriately adjusted by machine learning even in cases where adjustment is difficult, such as when the simulation models Ma and Mb include a relatively large number of parameters.

Each constituent component 210 includes the machining shaft 230 in addition to the robot 220. Accordingly, it is possible to appropriately and precisely generate an operation program for the robot system 200 including the machining shafts 230 in addition to the robots 220 from the viewpoint of power consumption.

### Modified Embodiments

Note that the embodiment disclosed this time must be considered as illustrative in all points and not restrictive. The scope of the present disclosure is not shown by the above description of the embodiments but by the scope of claims for patent, and all modifications (modified embodiments) within the meaning and scope equivalent to the scope of claims for patent are further included.

While the example in which the operation program generation apparatus includes the operation selector 12 that receives a selection of which operation to execute among an operation that prioritizes power consumption, an operation that prioritizes precision of the constituent components 210, and an operation that prioritizes operating speed of the constituent components 210 has been shown in the aforementioned embodiment, the present disclosure is not limited to this. For example, the operation selector 12 may receive a selection between an operation that prioritizes power consumption and an operation that prioritizes the precision of the constituent components 210 and operating speed of the constituent components 210.

While the example in which the input receiver 20 receives inputs of information on interlock of the constituent components 210, information on the constituent components 210 in operating and in standby, and information on disconnection of power supplies from the constituent components 210 has been shown in the aforementioned embodiment, the present disclosure is not limited to this. For example, the input receiver 20 may receive only one or two of these kinds of information.

While the example in which the power consumption calculator 14 simulates the power consumption of the robot system 200 including the difference in regenerative energy of the constituent components 210 has been shown in the aforementioned embodiment, the present disclosure is not limited to this. For example, the power consumption calculator 14 may simulate the power consumption of the robot system 200 without considering the difference in regenerative energy of the constituent components 210.

While the example in which the simulation model modifier 17 modifies parameters included in the simulation models Ma and Mb based on an error calculated by the error calculator 16 between the actual power consumption and the power consumption calculated by the simulation has been shown in the aforementioned embodiment, the present disclosure is not limited to this. For example, the operation program generation apparatus 100 may not include the error calculator 16 and the simulation model modifier 17. In this case, parameters included in the simulation models Ma and Mb are not modified.

While the example in which the robot system 200 includes the robots 220 and the machining shafts 230 has been shown in the aforementioned embodiment, the present disclosure is not limited to this. The present disclosure can be applied to a robot system 200 that does not include machining shafts 230 but includes the robots 220.

While the example in which, if an operator determines that the calculated power consumption values of the constituent components 210 and the calculated power consumption of the robot system 200 are not appropriate in step S7, the operator inputs modified information on operation of the robot system 200 using the input receiver 20 in step S2 has been shown in the aforementioned embodiment, the present disclosure is not limited to this. For example, if the calculated power consumption values of the constituent components 210 and the calculated power consumption of the robot system 200 are not appropriate, the information on operation of the robot system 200 may be optimized by machine learning or the like.

While the example in which inputs of working points, information on the workpieces and data on the facility are performed by an operator in step S1 has been shown in the aforementioned embodiment, the present disclosure is not limited to this. For example, working points, information on the workpieces and data on the facility may be optimized by machine learning.

Functions of elements disclosed in this specification can be realized by a circuit or processing circuit including a general-purpose processor, a dedicated processor, an integrated circuit, ASIC (Application Specific Integrated Circuits), a conventional circuit and/or combination of them configured or programmed to realize the functions disclosed. A processor is considered a processing circuit or circuits because it contains transistors and other circuitry. In the present disclosure, a circuit, unit, or means is hardware that performs an enumerated function or is hardware programmed to perform an enumerated function. The hardware may be the hardware disclosed herein or any other known hardware that is programmed or configured to perform the enumerated functions. If the hardware is a processor, which is considered a type of circuit, the circuit, means, or unit is a combination hardware and software, and software is used to configure the hardware and/or processor.

### Modes

The aforementioned exemplary embodiment will be understood as concrete examples of the following modes by those skilled in the art.

### Mode 1

An operation program generation apparatus includes an input receiver that receives an input of information on operation of a robot system including constituent components including robots; an operation program generator that generates a provisional operation program based on the input information on the operation; a power consumption calculator that simulates power consumption of the robot system when the constituent components are virtually operated according to the generated provisional operation program, wherein the input receiver receives an input of instruction to modify the information on the operation of the robot system based on a result of the simulated power consumption, and the operation program generator generates an actual operation program based on the modified information on the operation of the robot system.

### Mode 2

In the operation program generation apparatus according to mode 1, the operation program generator generates, as the provisional operation program, an operation trajectory of the constituent components when the constituent components are virtually operated; and the operation program generation apparatus comprises an operation selector that receives a selection of which operation to execute among an operation that prioritizes the power consumption, an operation that prioritizes precision of the constituent components, and an operation that prioritizes operating speed of the constituent components for each region of the generated operation trajectory.

### Mode 3

In the operation program generation apparatus according to mode 2, the power consumption calculator simulates the power consumption of the robot system when the constituent components are operated according to the operation trajectory that is prioritized by the selection for each region.

### Mode 4

In the operation program generation apparatus according to any of modes 1 to 3, the input receiver receives an input of information on interlock of at least one of the constituent components as the information on the operation of the robot system; and the power consumption calculator simulates the power consumption of the robot system including the constituent component that is interlocked.

### Mode 5

In the operation program generation apparatus according to any of modes 1 to 4, the input receiver receives inputs of information on the constituent components in operating and information on the constituent components on standby as the information on the operation of the robot system; and the power consumption calculator simulates the power consumption of the robot system including the constituent components in an operating state and the constituent components in a standby state.

### Mode 6

In the operation program generation apparatus according to any of modes 1 to 5, the input receiver receives an input of information on power disconnection of the constituent components as the information on the operation of the robot system; and the power consumption calculator simulates the power consumption of the robot system including the constituent components whose power is disconnected.

### Mode 7

In the operation program generation apparatus according to any of modes 1 to 6, the power consumption calculator simulates the power consumption of the robot system including a difference in regenerative energy of the constituent components.

### Mode 8

In the operation program generation apparatus according to mode 7, the power consumption calculator simulates, in a time series, the power consumption of the constituent components including the difference in regenerative energy of the constituent components.

### Mode 9

In the operation program generation apparatus according to any of modes 1 to 8, a storage that stores the actual operation program generated by the operation program generator is further provided.

### Mode 10

In the operation program generation apparatus according to any of modes 1 to 9, an operation program outputter that outputs the generated actual operation program to the robot system; and an error calculator that calculates an error between the actual power consumption of the constituent components when the constituent components are actually operated according to the actual operation program output from the operation program outputter and the power consumption calculated by the simulation are further provided.

### Mode 11

In the operation program generation apparatus according to mode 10, a simulation model modifier that modifies a parameter included in a simulation model simulating the power consumption of the robot system based on the error calculated by the error calculator is further provided.

### Mode 12

In the operation program generation apparatus according to mode 11, a machine learner that optimizes the parameter included in the simulation model using machine learning to reduce the error calculated by the error calculator is further provided.

### Mode 13

In the operation program generation apparatus according to any of modes 1 to 12, the constituent components include machining shafts in addition to the robots.

### Mode 14

An operation program generation method includes receiving an input of information on operation of a robot system including constituent components including robots; generating a provisional operation program based on the input information on the operation; simulating power consumption of the robot system when the constituent components are virtually operated according to the generated provisional operation program; receiving an instruction to modify the information on the operation of the robot system based on a result of the simulated power consumption; and generating an actual operation program based on the modified information on the operation of the robot system.

1. An operation program generation apparatus comprising:
an input receiver that receives an input of information on operation of a robot system including constituent components including robots;
an operation program generator that generates a provisional operation program based on the input information on the operation;
a power consumption calculator that simulates power consumption of the robot system when the constituent components are virtually operated according to the generated provisional operation program, wherein
the input receiver receives an input of instruction to modify the information on the operation of the robot system based on a result of the simulated power consumption, and
the operation program generator generates an actual operation program based on the modified information on the operation of the robot system.

2. The operation program generation apparatus according to claim 1, wherein
the operation program generator generates, as the provisional operation program, an operation trajectory of the constituent components when the constituent components are virtually operated; and
the operation program generation apparatus comprises an operation selector that receives a selection of which operation to execute among an operation that prioritizes the power consumption, an operation that prioritizes precision of the constituent components, and an operation that prioritizes operating speed of the constituent components for each region of the generated operation trajectory.

3. The operation program generation apparatus according to claim 2, wherein the power consumption calculator simulates the power consumption of the robot system when the constituent components are operated according to the operation trajectory that is prioritized by the selection for each region.

4. The operation program generation apparatus according to claim 1, wherein
the input receiver receives an input of information on interlock of at least one of the constituent components as the information on the operation of the robot system; and
the power consumption calculator simulates the power consumption of the robot system including the constituent component that is interlocked.

5. The operation program generation apparatus according to claim 1, wherein
the input receiver receives inputs of information on the constituent components in operating and information on the constituent components on standby as the information on the operation of the robot system; and
the power consumption calculator simulates the power consumption of the robot system including the constituent components in an operating state and the constituent components in a standby state.

6. The operation program generation apparatus according to claim 1, wherein
the input receiver receives an input of information on power disconnection of the constituent components as the information on the operation of the robot system; and
the power consumption calculator simulates the power consumption of the robot system including the constituent components whose power is disconnected.

7. The operation program generation apparatus according to claim 1, wherein the power consumption calculator simulates the power consumption of the robot system including a difference in regenerative energy of the constituent components.

8. The operation program generation apparatus according to claim 7, wherein the power consumption calculator simulates, in a time series, the power consumption of the constituent components including the difference in regenerative energy of the constituent components.

9. The operation program generation apparatus according to claim 1 comprising a storage that stores the actual operation program generated by the operation program generator.

10. The operation program generation apparatus according to claim 1 comprising:
an operation program outputter that outputs the generated actual operation program to the robot system; and
an error calculator that calculates an error between the actual power consumption of the constituent components when the constituent components are actually operated according to the actual operation program output from the operation program outputter and the power consumption calculated by the simulation.

11. The operation program generation apparatus according to claim 10 comprising a simulation model modifier that modifies a parameter included in a simulation model simulating the power consumption of the robot system based on the error calculated by the error calculator.

12. The operation program generation apparatus according to claim 11 comprising a machine learner that optimizes the parameter included in the simulation model using machine learning to reduce the error calculated by the error calculator.

13. The operation program generation apparatus according to claim 1, wherein the constituent components include machining shafts in addition to the robots.

14. An operation program generation method comprising:
receiving an input of information on operation of a robot system including constituent components including robots;
generating a provisional operation program based on the input information on the operation;
simulating power consumption of the robot system when the constituent components are virtually operated according to the generated provisional operation program;
receiving an instruction to modify the information on the operation of the robot system based on a result of the simulated power consumption; and
generating an actual operation program based on the modified information on the operation of the robot system.
